(19) United States
(12) Patent Application Publication
(10) Pub. No.: US 2025/0267891 A1
(43) Pub. Date: Aug. 21, 2025

(54) LATERAL DIFFUSED SEMICONDUCTOR DEVICE AND FORMING METHOD THEREOF

(71) Applicants: TAIWAN SEMICONDUCTOR MANUFACTURING COMPANY, LTD., Hsinchu (TW); TSMC CHINA COMPANY LIMITED, Shanghai (CN)

(72) Inventors: Tsung-Yi HUANG, Hsinchu County (TW); Lianjie LI, Shanghai City (CN); LinChun GUI, Shanghai City (CN); Xuepeng LI, Shanghai City (CN)

(73) Assignees: TAIWAN SEMICONDUCTOR MANUFACTURING COMPANY, LTD., Hsinchu (TW); TSMC CHINA COMPANY LIMITED, Shanghai (CN)

(21) Appl. No.: 18/595,016

(22) Filed: Mar. 4, 2024

(30) Foreign Application Priority Data
Feb. 20, 2024 (CN) 202420316324.5

(51) Int. Cl. H01L 29/78; H01L 29/06; H01L 29/66

(52) U.S. Cl. CPC H10D 30/65; H10D 30/0281; H10D 62/102

(57) ABSTRACT

A semiconductor device includes a p-type epitaxial layer over a substrate, a plurality of n-type wells in the p-type epitaxial layer, a p-type well interfacing a first one of the plurality of n-type wells, a first n-type buried layer in the substrate, a source region in the p-type well, a drain region in a second one of the plurality of n-type wells, and a gate structure laterally between the source region and the drain region. Each of the plurality of n-type wells has a bottom surface entirely in contact with the substrate. The p-type well overlaps with an entirety of the first n-type buried layer.

### PRIORITY CLAIM AND CROSS-REFERENCE

This application claims priority to China Application Serial Number 202420316324.5, filed Feb. 20, 2024, which is herein incorporated by reference.

### BACKGROUND

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node (e.g., shrink the process node towards the sub-20 nm node). As semiconductor devices are scaled down, new techniques are desired to maintain the electronic components' performance from one generation to the next. For example, low on-resistance and high breakdown voltage of transistors are desirable for various high power applications.

According to the polarity difference, MOSFETs may include two major categories. One is n-channel MOSFETs; the other is p-channel MOSFETs. On the other hand, according to the structure difference, MOSFETs can be further divided into three sub-categories, planar MOSFETs, lateral diffused MOS (LDMOS) FETs and vertical diffused MOSFETs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 14 illustrate cross-sectional views of intermediate stages in the formation of LDMOS devices in accordance with some embodiments of the present disclosure.

FIG. 15 is a flow chart illustrating a method of forming LDMOS devices in accordance with some embodiments of the present disclosure.

FIG. 16 illustrates a cross-sectional view of LDMOS devices in accordance with some embodiments of the present disclosure.

FIG. 17 illustrates a cross-sectional view of LDMOS devices in accordance with some embodiments of the present disclosure.

FIG. 18 illustrates a cross-sectional view of LDMOS devices in accordance with some embodiments of the present disclosure.

FIG. 19 illustrates a cross-sectional view of LDMOS devices in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The present disclosure will be described with respect to embodiments in a specific context, a lateral diffused metal oxide semiconductor (LDMOS) field effect transistor, and more particularly, an n-type lateral metal oxide semiconductor (NLDMOS) transistor. The embodiments of the disclosure may also be applied, however, to a variety of metal oxide semiconductor transistors. Hereinafter, various embodiments will be explained in detail with reference to the accompanying drawings. LDMOS devices are widely used in various high power applications, such as a DC-DC Buck converter, an AC-DC Flyback controller, motor driver, and so on. A limiting factor for these high power applications is the breakdown voltage of the LDMOS devices. Therefore, the present disclosure, in various embodiments, provides LDMOS devices with improved configurations of doped regions tailored to improve the breakdown voltage of the LDMOS devices to be higher than, for example, 100 volts.

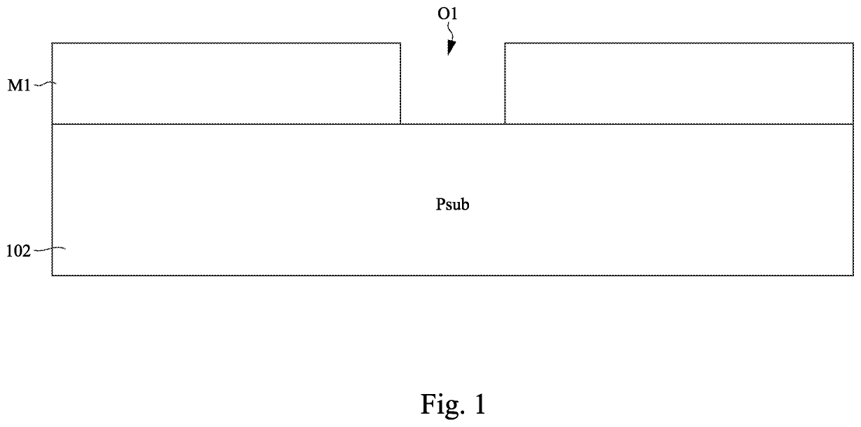

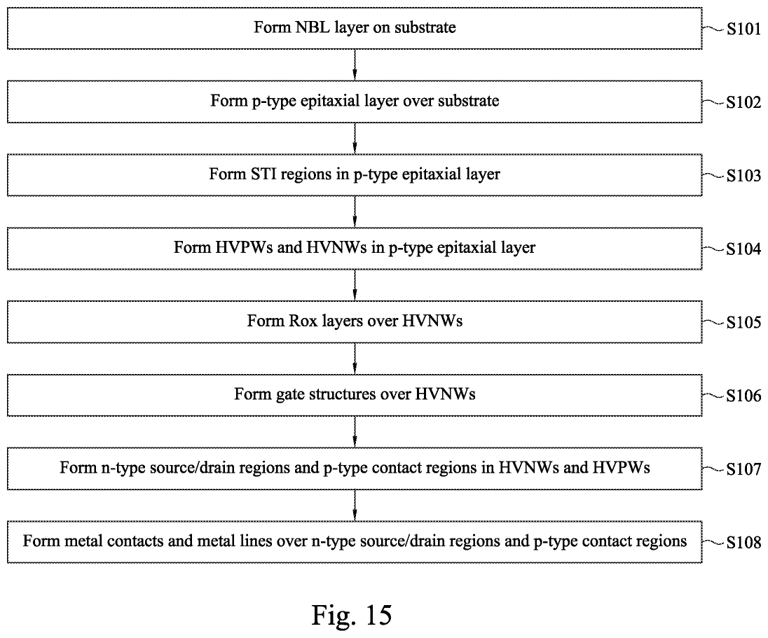

FIGS. 1 through 14 illustrate cross-sectional views of intermediate stages in the formation of transistors in accordance with some embodiments of the present disclosure. The steps shown in FIGS. 1 through 14 are also reflected schematically in the process flow shown in FIG. 15. The formed transistors include adjacent LDMOS transistors sharing a common source terminal in accordance with some exemplary embodiments. Throughout the various views and illustrative embodiments, like reference numbers are used to designate like elements. It is understood that additional operations can be provided before, during, and after the processes shown by FIGS. 1-14, and some of the operations described below can be replaced or eliminated, for additional embodiments of the method. The order of the operations/processes may be interchangeable.

FIG. 1 illustrates a cross-sectional view of an initial structure. The initial structure includes a semiconductor substrate 102. The semiconductor substrate 102 may include a semiconductor wafer such as a silicon wafer. Alternatively, the semiconductor substrate 102 may include other elementary semiconductors such as germanium. The semiconductor substrate 102 may also include a compound semiconductor such as silicon carbide, gallium arsenic, indium arsenide, and indium phosphide. Moreover, the semiconductor substrate 102 may include an alloy semiconductor such as silicon germanium, silicon germanium carbide, gallium arsenic phosphide, and gallium indium phosphide. In the some embodiments, the semiconductor substrate 102 includes a p-type silicon substrate (p-substrate), labeled “Psub” in FIG. 1.

FIG. 1 also illustrates a patterned mask layer M1 formed over the substrate 102 to define a location of an n-type buried layer (NBL) 104 subsequently formed in the substrate 102. The patterned mask layer M1 may comprise an organic material, such as a photoresist material, and may be formed using a spin-on coating process, followed by patterning the photoresist material, using suitable lithography techniques, to forming one or more openings O1 extending through the patterned mask layer M1 to expose a target region of the substrate 102. For example, photoresist material is irradiated (exposed) and developed to remove portions of the photoresist material. In greater detail, a photomask (not shown) may be placed over the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material, and a developer may be used to remove either the exposed or unexposed portions of the photoresist material depending on whether a positive or negative resist is used.

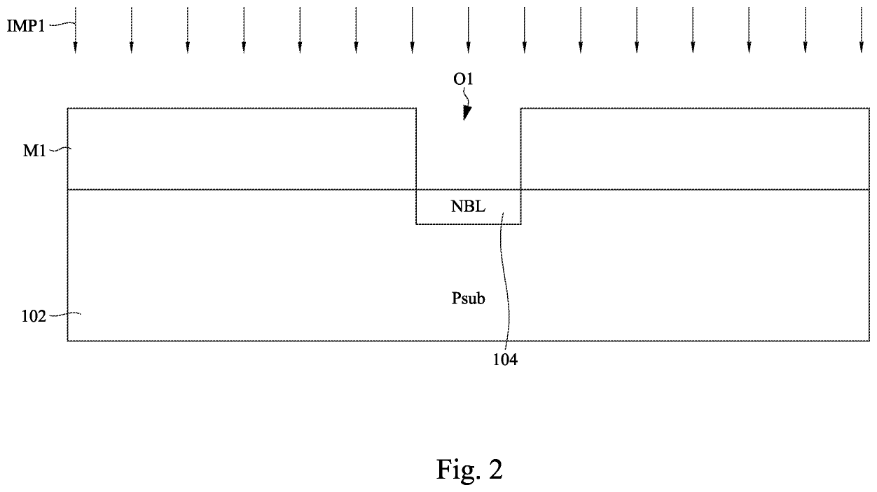

In FIG. 2, with the patterned mask layer M1 in place, an n-type ion implantation process IMP1 is performed to dope an n-type impurity (e.g., phosphorus, arsenic, antimony, or the like) into the p-type substrate 102 to form an n-type buried layer (NBL) 104. The n-type ion implantation is performed using the patterned mask layer M1 as an implantation mask, such that the NBL 104 has a top-view pattern or geometry inheriting the top-view pattern or geometry of the opening O1 of the patterned mask layer M1. In this way, the top-view pattern of the opening O1 can be designed to define a desired top-view pattern of the NBL 104. In some embodiments, the n-type ion implantation process IMP1 is performed to implant the n-type impurity at a dose of about 1E13 atoms/cm³ to about 1E15 atoms/cm³, and at an energy of about 50 KeV to about 200 KeV.

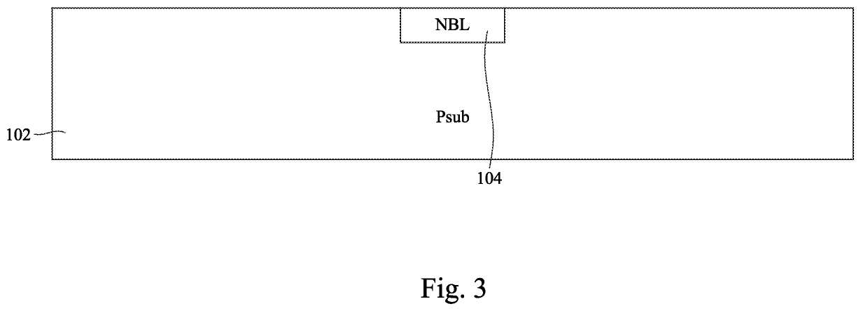

In FIG. 3, after forming the NBL 104, the patterned mask layer M1 is removed, for example, using a plasma ash process. In some embodiments, a plasma ash process is performed such that the temperature of the photoresist mask M1 is increased until the photoresist mask M1 experiences a thermal decomposition and may be removed. However, any other suitable process, such as a wet strip, may be utilized.

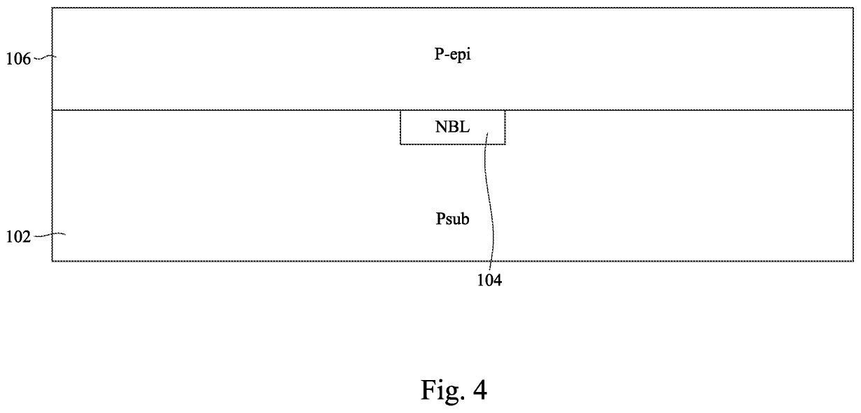

In FIG. 4, a p-type epitaxial layer 106, labeled “P-epi” in FIG. 4, is formed over the p-type substrate 102 and the NBL 104. In some embodiments, the p-type epitaxial layer 106 is a crystalline semiconductor material (e.g., silicon, germanium, or silicon germanium) formed using a suitable epitaxial growth method such as e.g., vapor/solid/liquid phase epitaxy (VPE, SPE, LPE), or metal-organic CVD (MOCVD), or molecular beam epitaxy (MBE), or the like. A dose of p-type impurity (e.g., boron, boron fluoride, indium, or the like) is introduced into the epitaxially grown material either in situ during the epitaxial growth, or by an ion implantation process performed after the epitaxial growth, or by a combination thereof. In some embodiments, the p-type epitaxial layer 106 has a thickness in a range from about 5 μm to about 10 μm, and a resistivity in a range from about 10 ohm-cm to about 100 ohm-cm, which aids in preventing leakage and improving breakdown voltage.

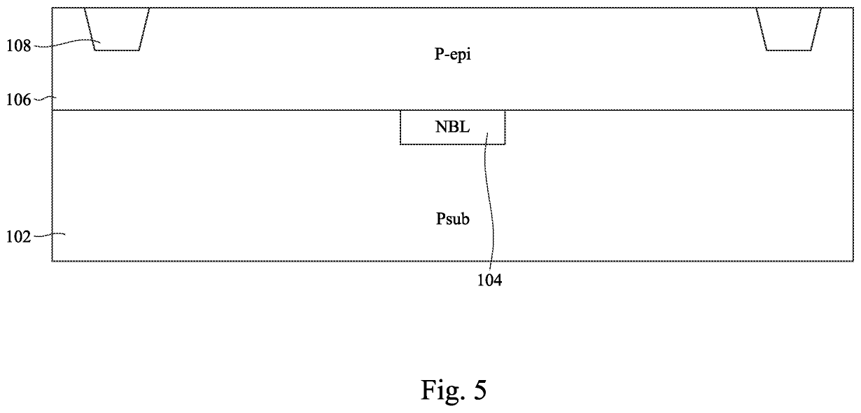

In FIG. 5, isolation structures 108 such as shallow trench isolation (STI) regions or local oxidation of silicon (LOCOS) (or field oxide, FOX) regions including isolation features may be formed in the p-type epitaxial layer 106 to define and electrically isolate various active regions so as to prevent leakage current from flowing between adjacent active regions. As one example, the formation of an STI feature may include dry etching a trench in a substrate and filling the trench with insulator materials such as silicon oxide, silicon nitride, or silicon oxynitride. The filled trench may have a multi-layer structure such as a thermal oxide liner layer filled with silicon nitride or silicon oxide. In some other embodiments, the STI structure may be created using a processing sequence such as: growing a pad oxide, forming a low pressure chemical vapor deposition (LPCVD) nitride layer, patterning an STI opening using photoresist and masking, etching a trench in the substrate, optionally growing a thermal oxide trench liner to improve the trench interface, filling the trench with CVD oxide, using chemical mechanical polishing (CMP) processing to etch back and planarize, and using a nitride stripping process to remove the silicon nitride.

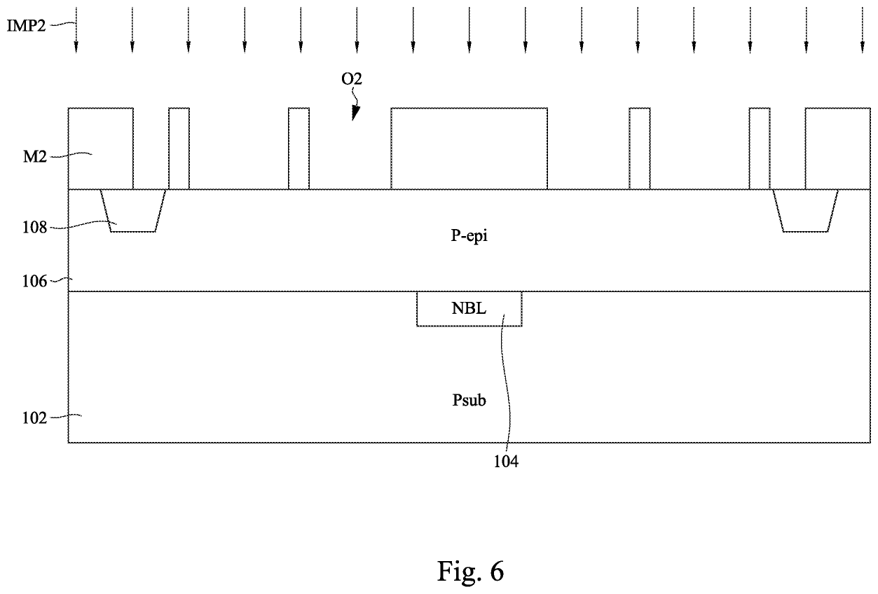

In FIG. 6, a patterned mask layer M2 is formed over the p-type epitaxial layer 106 to define locations of high voltage N-wells (HVNWs) 110, locations of high voltage P-wells (HVPW) 112, and locations of p-type slots 114 formed in subsequent processing. The patterned mask layer M2 may comprise an organic material, such as a photoresist material, and may be formed using a spin-on coating process, followed by patterning the photoresist material, using suitable lithography techniques, to forming one or more openings O2 extending through the patterned mask layer M2 to expose HVNW target regions of the p-type epitaxial layer 106. For example, photoresist material is irradiated (exposed) and developed to remove portions of the photoresist material. In greater detail, a photomask (not shown) may be placed over the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material, and a developer may be used to remove either the exposed or unexposed portions of the photoresist material depending on whether a positive or negative resist is used.

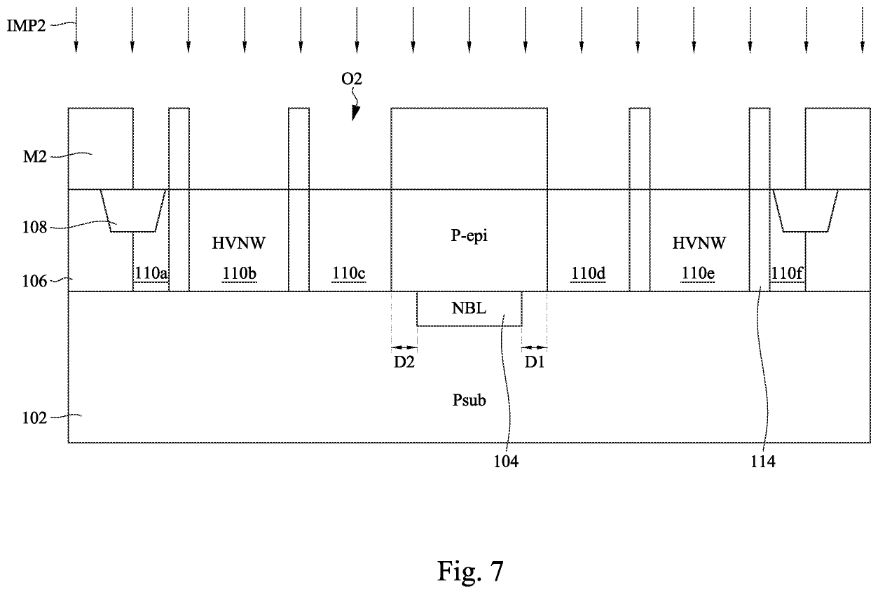

In FIG. 7, with the patterned mask layer M2 in place, an n-type ion implantation process IMP2 is performed to dope an n-type impurity (e.g., phosphorus, arsenic, antimony, or the like) into the p-type epitaxial layer 106 to form high voltage N-wells (HVNWs) 110a, 110b, 110c, 110d, 110e, 110f. These N-wells 110a-110f are collectively referred to as HVNWs 110. The n-type ion implantation IMP2 is performed using the patterned mask layer M2 as an implantation mask, such that each HVNW 110 has a top-view pattern or geometry inheriting the top-view pattern or geometry of the corresponding opening O2 of the patterned mask layer M2. In this way, the top-view pattern of the opening O2 can be designed to define a desired top-view pattern of the HVNW 110. In some embodiments, the n-type ion implantation process IMP2 is performed to implant the n-type impurity at a dose of about 1E12 atoms/cm³ to about 1E13 atoms/cm³, and at an energy of about 50 KeV to about 3000 KeV.

In some embodiments, the HVNWs 110 have an n-type impurity concentration less than an n-type impurity concentration of the NBL 104. In some embodiments, the pattern of the patterned mask layer M2 is designed in such a way that none of HVNWs 110 vertically overlaps with the NBL 104. In particular, the NBL 104 has a right sidewall boundary laterally set back from a left sidewall boundary of a right HVNW 110d by a non-zero distance D1, and the NBL 104 has a left sidewall boundary laterally set back from a right sidewall boundary of a right HVNW 110c by a non-zero distance D2, and thus the NBL 104 can be localized to source sides of resulting LDMOS devices, improving electrical isolation properties and hence the breakdown voltage of resulting LDMOS devices. In some embodiments, the non-zero distance D1 is the same as the non-zero distance D2. In some other embodiments, the non-zero distance D1 is different from (e.g., greater than or less than) the non-zero distance D2.

In some embodiments, each HVNW 110 has a depth P1 substantially the same as the thickness of the p-type epitaxial layer 106. Stated differently, each HVNW 110 extends vertically through a full thickness of the p-type epitaxial layer 106 and terminates the top surface of the p-type substrate 102. Because the NBL 104 is formed within the p-type substrate 102, the top surface of the NBL 104 is level with the bottom surface of the HVNW 110 without overlapping it. In contrast to conventional LDMOS devices, which might have deep p-wells (DPWs) formed in p-type epitaxial layer and HVNWs formed over the DPWs, resulting in elevated horizontal p-n junctions, the improved configuration as illustrated in FIG. 7 ensures that horizontal p-n junctions occur at the top surface of the p-type substrate 102. This design improves vertical junction breakdown and enhances the breakdown voltage.

In some embodiments, slot regions 114 of the p-type epitaxial layer 106 are masked by the patterned mask layer M2, and therefore these regions 114 are un-doped by the ion implantation process IMP2 and retain their p-type characteristics. These regions 114, also called p-type slots or p-type slot regions 114 in this context, are alternately arranged with the HVNWs 110 in a horizontal direction. Specifically, each p-type slot 114 interposes adjacent two of the HVNWs 110 without extra implantation step and associated implantation mask. Such alternating arrangement can improve the lateral P-N junction breakdown, thereby further boosting the breakdown voltage of resulting LDMOS devices. In some embodiments, each p-type slot 114 may have a light n-type impurity concentration less than the n-type impurity concentration of the HVNWs 110, because of the unintentional lateral diffusion from the HVNWs 110. Although four p-type slots 114 are formed between STI regions 108 in the illustrated embodiment, additional p-type slots 114 can be included between the STI regions 108 to further improve the breakdown voltage. In some embodiments, the multiple p-type slots 114 are located at a “non-NBL region,” i.e., the region that does not overlap with the NBL layer 104 on the p-type substrate 102. This design serves to enhance the reduced surface field (RESURF) effect around transistor drain regions, thus improving the breakdown voltages of the resulting LDMOS devices. In particular, by forming the p-type slots 114 non-overlapping with the NBL layer 104, the electric field at the surface of the p-type epitaxial layer 106 can be reduced, thus improving the breakdown voltage. In some embodiments, each p-type slot 114 has a slot width in a range from about 0.5 μm to about 2 μm.

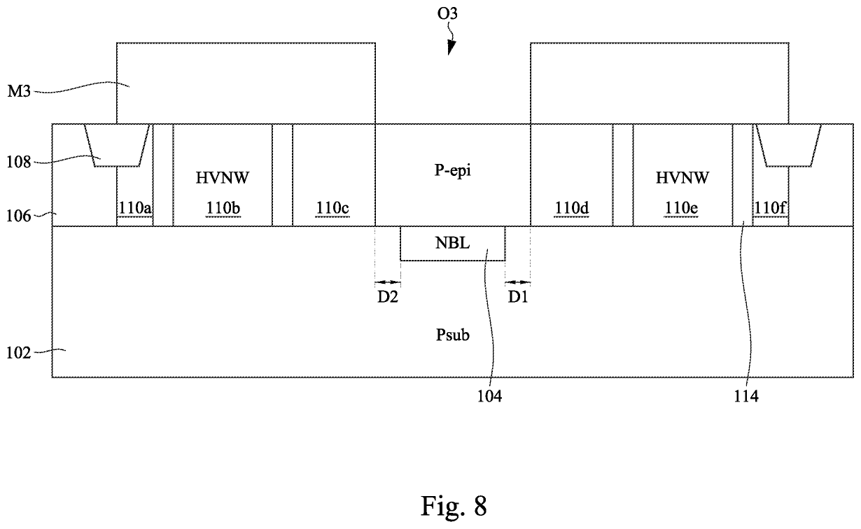

In FIG. 8, after forming HVNWs 110, the patterned mask layer M2 is removed, for example, using a plasma ash process. In some embodiments, a plasma ash process is performed such that the temperature of the photoresist mask M2 is increased until the photoresist mask M2 experiences a thermal decomposition and may be removed. However, any other suitable process, such as a wet strip, may be utilized.

Next, another patterned mask layer M3 is formed over the p-type epitaxial layer 106 to define locations of high voltage P-wells (HVPW) 112 formed in subsequent processing. The patterned mask layer M3 may comprise an organic material, such as a photoresist material, and may be formed using a spin-on coating process, followed by patterning the photoresist material, using suitable lithography techniques, to forming one or more openings O3 extending through the patterned mask layer M3 to expose HVPW target regions of the p-type epitaxial layer 106. For example, photoresist material is irradiated (exposed) and developed to remove portions of the photoresist material. In greater detail, a photomask (not shown) may be placed over the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material, and a developer may be used to remove either the exposed or unexposed portions of the photoresist material depending on whether a positive or negative resist is used.

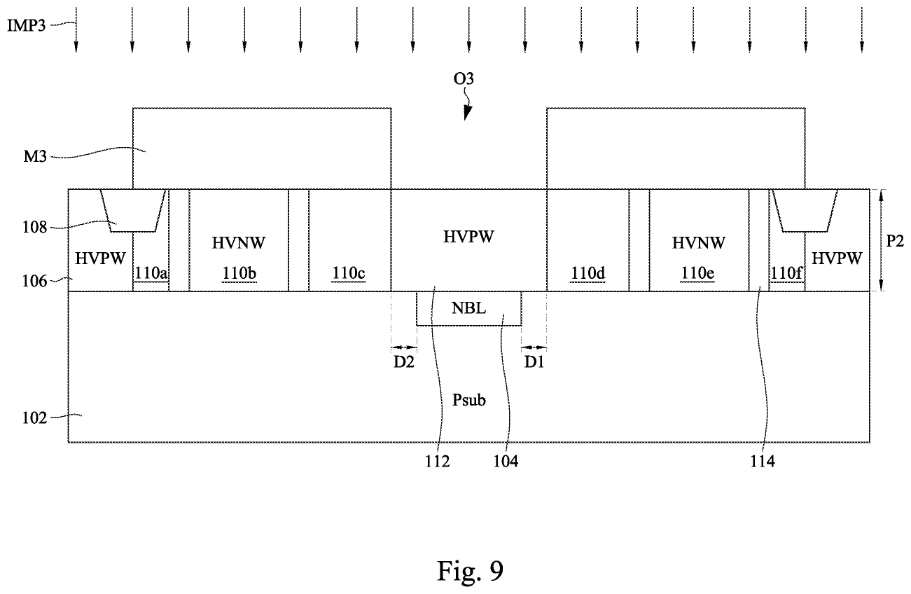

In FIG. 9, with the patterned mask layer M3 in place, a p-type ion implantation process IMP3 is performed to dope a p-type impurity (e.g., boron, boron fluoride, indium, or the like) into the p-type epitaxial layer 106 to form high voltage P-wells (HVPWs) 112 interfacing the HVNWs 110a, 110c, 110d, 110f. The p-type ion implantation IMP3 is performed using the patterned mask layer M3 as an implantation mask, such that each HVPW 110 has a top-view pattern or geometry inheriting the top-view pattern or geometry of the corresponding opening O3 of the patterned mask layer M3. In this way, the top-view pattern of the opening O3 can be designed to define a desired top-view pattern of the HVPW 112. For example a HVPW 112 forms an interface with the HVNW 110c and an interface with HVNW 110d. In some embodiments, the p-type ion implantation process IMP3 is performed to implant the p-type impurity at a dose of about 1E12 atoms/cm³ to about 1E13 atoms/cm³, and at an energy of about 50 KeV to about 3000 KeV.

In some embodiments, the HVPW 112 has a p-type impurity concentration less than an n-type impurity concentration of the NBL 104. In some embodiments, the pattern of the patterned mask layer M3 is designed in such a way that a HVPW 112 vertically overlaps with an entirety of the NBL 104. In particular, the HVPW 112 has a bottom surface extending laterally past opposite sidewall boundaries to reach the HVNWs 110. The NBL 104 has a right sidewall boundary laterally set back from a right sidewall boundary of the HVPW 112 by a non-zero distance D1, and the NBL 104 has a left sidewall boundary laterally set back from a left sidewall boundary of the HVPW 112 by a non-zero distance D2, and thus the NBL 104 can be localized to directly below source regions subsequently formed in the HVPW 112, thereby improving electrical isolation properties and hence the breakdown voltage of resulting LDMOS devices.

In some embodiments, each HVPW 112 has a depth P2 substantially the same as the thickness of the p-type epitaxial layer 106. Stated differently, the HVPW 112 extends vertically through a full thickness of the p-type epitaxial layer 106 and terminates the top surface of the p-type substrate 102. Because the NBL 104 is formed within the p-type substrate 102, the top surface of the NBL 104 is level with the bottom surface of the HVPW 112 and entirely overlaps with it. Moreover, because the HVNWs 110 also extend vertically through a full thickness of the p-type epitaxial layer 106, the bottom surfaces of the HVNWs 110 are level with the bottom surfaces of the HVPWs 112. In some embodiments, the p-type slots 114 are masked by the patterned mask layer M3 during the ion implantation process IMP3, and therefore these p-type slots 114 are un-doped by the ion implantation process IMP3 and thus have a lower p-type impurity concentration than the HVPWs 112.

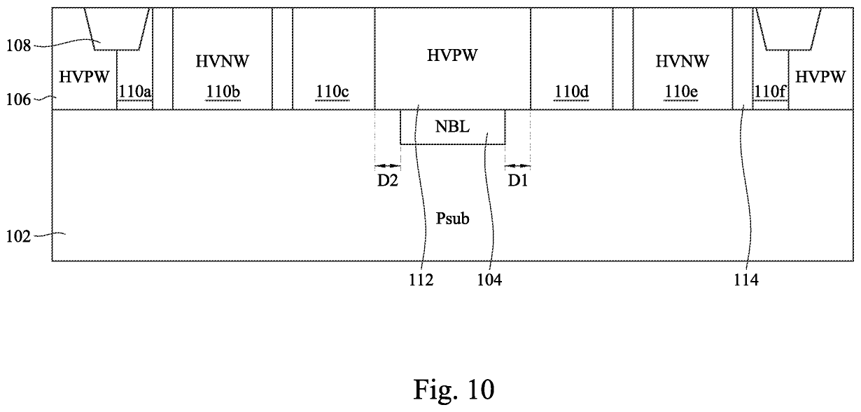

In FIG. 10, after forming HVPWs 112, the patterned mask layer M3 is removed, for example, using a plasma ash process. In some embodiments, a plasma ash process is performed such that the temperature of the photoresist mask M3 is increased until the photoresist mask M3 experiences a thermal decomposition and may be removed. However, any other suitable process, such as a wet strip, may be utilized.

FIGS. 6-10 show exemplary sequential processes that include forming HVNWs 110, followed by forming HVPWs 112. However, in some alternative embodiments, the HVPWs 112 can be formed in the p-type epitaxial layer 106 in advance by using suitable patterned mask layer as an implantation mask, followed by forming the HVNWs 110 in the p-type epitaxial layer 106 by using another patterned mask layer as an implantation mask.

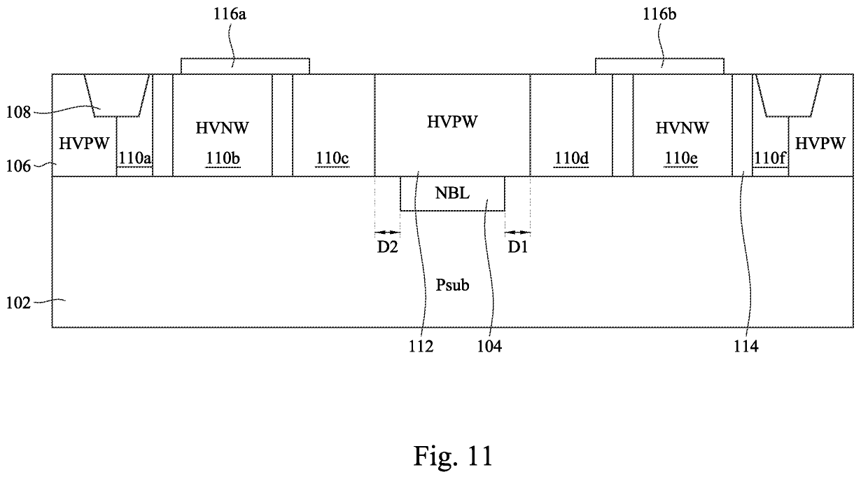

In FIG. 11, RESURF oxide (Rox) layers 116a and 116b are formed over the HVNWs 110b, 110c and 110d, 110e, respectively. Each of the Rox layers 116a and 116b is disposed over a corresponding p-type slot region 114. In some embodiments, the Rox layers 116a and 116b can be formed by, for example, depositing or growing an oxide layer (e.g., SiO₂ layer) spanning the p-type epitaxial layer 106, followed by patterning the oxide layer into the Rox layers 116a and 116b by using suitable etching techniques (e.g., dry etching, wet etching or combinations thereof). The Rox layers 116a and 116b serve to reduce the electric filed at the top surface of the p-type epitaxial layer 106, especially drift regions of LDMOS devices, where breakdown is likely to occur. By reducing the surface field using the Rox layers 116a and 116b, the breakdown voltage of resulting LDMOS devices can be further improved. In some embodiments, one or more STI regions are formed in the drift regions directly below the Rox layers 116a and 116b.

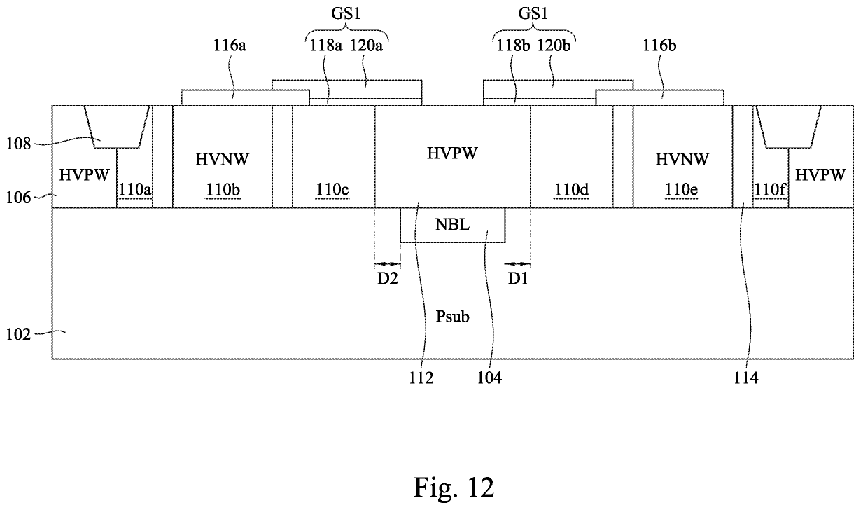

In FIG. 12, gate dielectric layers 118a and 118b are formed over the p-type epitaxial layer 106, followed by forming gate electrodes 120a and 120b over the respective gate dielectric layers 118a and 118b. The gate dielectric layer 118a and the overlying gate electrode 120a collectively serve as a gate structure GS1 extending over the Rox layer 116a and across an interface between the HVPW 112 and a left HVNW 110c. The gate dielectric layer 118b and the overlying gate electrode 120b collectively serve as a gate structure GS2 extending over the Rox layer 116b and across an interface between the HVPW 112 and a right HVNW 110d. In some embodiments, the gate structures GS1 and GS2 are formed by, for example, growing an oxide layer on top surface of the p-type epitaxial layer 106 using a thermal oxidation process or an in-situ steam generation (ISSG) process, depositing a gate electrode layer over the oxide layer, followed by patterning the gate electrode layer and the oxide layer into gate electrodes 120a, 120b, and gate dielectric layers 118a and 118b using suitable photolithography and etching techniques.

The resultant gate dielectric layer 118a has a right side surface coterminous or aligned with a right side surface of the gate electrode 120a, and a left side surface in contact with a right side surface of the Rox layer 116a and thus offset from a left side surface of the gate electrode 120a. Similarly, the gate dielectric layer 118b has a left side surface coterminous or aligned with a left side surface of the gate electrode 120b, and a right side surface in contact with a left side surface of the Rox layer 116b and thus offset from a right side surface of the gate electrode 120b In some embodiments, the gate dielectric layers 118a and 118b have a thickness less than a thickness of the Rox layers 116a and 116b, because the Rox layers 116a and 116b play a different role than the gate dielectric layers 118a and 118b. In particular, the thickness of the Rox layers 116a and 116b are tailored to achieve desired electric field reduction in the drift regions of LDMOS, and thus have a greater thickness than the gate dielectric layers 118a and 118b.

In some embodiments, the gate dielectric layers 118a and 118b have a same material (e.g., silicon oxide) as the Rox layers 116a and 116b. In some other embodiments, the gate dielectric layer 118a and 118b have a different material than the Rox layers 116a and 116b. For example, the gate dielectric layers 118a and 118b may optionally include a high-k dielectric material, silicon oxynitride, other suitable materials, or combinations thereof. The high-k material may be selected from metal oxides, metal nitrides, metal silicates, transition metal-oxides, transition metal-nitrides, transition metal-silicates, oxynitrides of metals, metal aluminates, zirconium silicate, zirconium aluminate, hafnium oxide, or combinations thereof. The gate dielectric layers 118a and 118b may have a multilayer structure such as one layer of silicon oxide and another layer of high-k material. The gate dielectric layers 118a and 118b may be formed using chemical vapor deposition (CVD), physical vapor deposition (PVD), atomic layer deposition (ALD), thermal oxide, other suitable processes, or combinations thereof.

In some embodiments, the gate electrodes 120a and 120b may include a doped polycrystalline silicon (or polysilicon). Alternatively, the gate electrodes 120a and 120b may include a metal such as Al, Cu, W, Ti, Ta, TiN, TaN, NiSi, CoSi, other suitable conductive materials, or combinations thereof. The gate electrodes 120a and 120b may be formed by CVD, PVD, plating, and other proper processes. The gate electrodes 120a and 120b may have a multilayer structure and may be formed in a multi-step process using a combination of different processes.

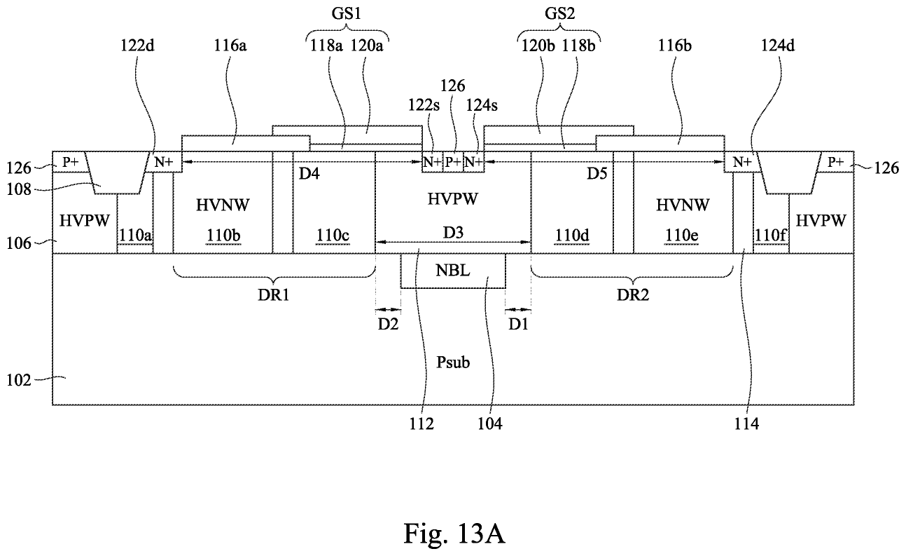

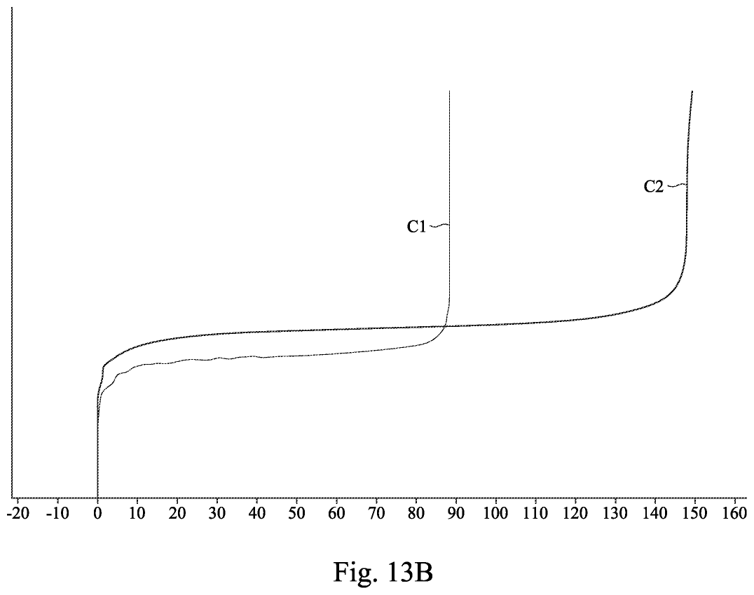

In FIG. 13A, n-type source regions 122s and 124s are formed in the HVPW 112, and n-type drain regions 122d and 124d are formed in the respective HVNWs 110. In particular, the n-type drain region 122d is formed in HVNWs 110a, 110b and over a p-type slot region 114. The p-type slot region 114 directly below the n-type drain region 122d thus has a less height (or a lower top surface) than the p-type slot region 114 directly below the gate structure GS1. Similarly, the n-type drain region 124d is formed in HVNWs 110e, 110f and over a p-type slot region 114. The p-type slot region 114 directly below the n-type drain region 124d has a less height (or a lower top surface) than the p-type slot region 114 directly below the gate structure GS2.

The n-type source/drain regions are formed using an n-type ion implantation process to dope an n-type impurity (e.g., phosphorus, arsenic, antimony, or the like) into target portions within the HVPW 112 and the HVNWs 110. In some embodiments, the n-type source region 122s and the n-type drain region 122d have a higher n-type impurity concentration than an n-type impurity concentration within the HVNW 110 and a p-type impurity concentration within the HVPW 112. The n-type source region 122s, the n-type drain region 122d and the gate structure GS1 collectively act as an n-type LDMOS with the gate electrode 120a as its gate terminal, n-type source region 122s as its source terminal, and drain region 122d as its drain terminal. Similarly, the n-type source region 124s and the n-type drain region 124d have a higher n-type impurity concentration than an n-type impurity concentration within the HVNW 110 and a p-type impurity concentration within the HVPW 112. The n-type source region 124s, the n-type drain region 124d and the gate structure GS2 collectively act as another n-type LDMOS with the gate electrode 120b as its gate terminal, n-type source region 124s as its source terminal, and drain region 124d as its drain terminal. In some embodiments, the dopant concentration of the n-type source/drain regions 122s/122d, and 124s/124d is in a range from about 10¹⁹ atoms/cm³ to about 10²⁰ atoms/cm³, and other dopant concentration ranges are within the scope of the present disclosure.

FIG. 13A also illustrates p-type contact regions 126 formed in respective HVPWs 112. The p-type contact regions 126 are formed using a p-type ion implantation process to dope a p-type impurity (e.g., boron, boron fluoride, indium, or the like) into target portions within the HVPWs 112. In some embodiments, the p-type contact regions 126 have a higher p-type impurity concentration than a p-type impurity concentration within the HVPWs 112, and serve as substrate contacts and/or bulk contacts for the integrated circuit structure.

In some embodiments, after the ion implantation process for forming the n-type source/drain regions 122s/122d and 124s/124d, an anneal may be performed to repair implant damage and to activate the p-type and/or n-type impurities that were implanted.

The LDMOS device on the left side of HVPW 112 has drift region DR1 with a drift region length D4 extending laterally from the n-type drain region 122d to the left side sidewall boundary of the HVPW 112. In some embodiments, a ratio of the non-zero distance D2 to the drift region length D4 is less than ¼. If the ratio is excessively large (e.g., much greater than ¼), the NBL layer 104 may be excessively narrow, resulting in potential unwanted leakage path between the HVPW 112 and the p-type substrate 102. If the ratio is excessively small (e.g., less than 1/10), the NBL layer 104 may be excessively wide, leading to lowered breakdown voltage. In some embodiments, the drift region length D4 in the left LDMOS device is in a range from 5 μm to 15 μm. In some embodiments, the HVPW 112 has a width D3 in a range from 1 μm to 3 μm.

The LDMOS device on the right side of HVPW 112 has drift region DR2 with a drift region length D5 extending laterally from the n-type drain region 124d to the right side sidewall boundary of the HVPW 112. In some embodiments, a ratio of the non-zero distance D1 to the drift region length D4 is less than ¼. If the ratio is excessively large (e.g., much greater than ¼), the NBL layer 104 may be excessively narrow, resulting in potential unwanted leakage path between the HVPW 112 and the p-type substrate 102. If the ratio is excessively small (e.g., less than 1/10), the NBL layer 104 may be excessively wide, leading to lowered breakdown voltage. In some embodiments, the drift region length D5 in the right LDMOS device is in a range from 5 μm to 15 μm. In some embodiments, the drift region length D4 in the left LDMOS device is the same as the drift region length D5 in the right LDMOS device. In some embodiments, the drift region length D4 in the left LDMOS device is different from (e.g., less than or greater than) the drift region length D5 in the right LDMOS device.

The gate structure GS1 overlaps with a p-type slot 114 within the p-type epitaxial layer 106. In particular, an edge region of the gate structure GS1 over the Rox layer 116a overlaps with a p-type slot 114. Moreover, the n-type drain region 122d overlaps with a p-type slot 114. Similarly, an edge region of the gate structure GS2 over the Rox layer 116b overlaps with a p-type slot 114, and the n-type drain region 124d overlaps with a p-type slot 114. By using the p-type slots 114 localized to gate edge regions and drain regions, the breakdown voltage of the LDMOS devices can be improved. The NBL layer 104 overlaps with the n-type source regions 122s and 124s and non-overlaps with the n-type drain regions 122d and 124d. By using the NBL layer 104 localized to source sides of LDMOS devices, the breakdown voltage of the LDMOS devices can be improved.

FIG. 13B illustrates simulation results showing breakdown voltage improvement resulting from the structure as illustrated in FIG. 13A. FIG. 13B is a graph showing current-voltage characteristics of LDMOS devices, obtained from simulations prepared using device simulation software, also referred to as technology computer-aided design (TCAD). In FIG. 13B, the logarithm drain current (Log I_{d}) is shown on the vertical axis, and the drain voltage (V_{D}) is shown on the horizontal axis. The I-V curve C1 represents a current-voltage characteristic of a LDMOS device having an NBL layer extending to directly below drain region and DPWs formed vertically between the NBL layer and the drain region. The I-V curve C2 represents a current-voltage characteristic of a LDMOS device as illustrated in FIG. 13A. The I-V curves C1 and C2 indicate breakdown voltages at a point where the current sharply increases as almost no voltage increases, i.e., at approximately an inflection point of these curves. The I-V curve C1 indicates a breakdown voltage between about 85 volts (V) to about 100 V (e.g., 90 V). The I-V curve C2 indicates a breakdown voltage between about 140 V to about 160V (e.g., 150V). These simulation results show that the breakdown voltage of LDMOS device can be improved, e.g., from 90V to 150V, by using the localized NBL layer 104, deepened HVNWs 110, and the p-type slots 114 alternately arranged with the deepened HVNWs 110, as illustrated in FIG. 13A. This improvement in breakdown voltage is attributed to an improved electric potential profile, specifically achieving a lower potential at the source sides of the LDMOS devices.

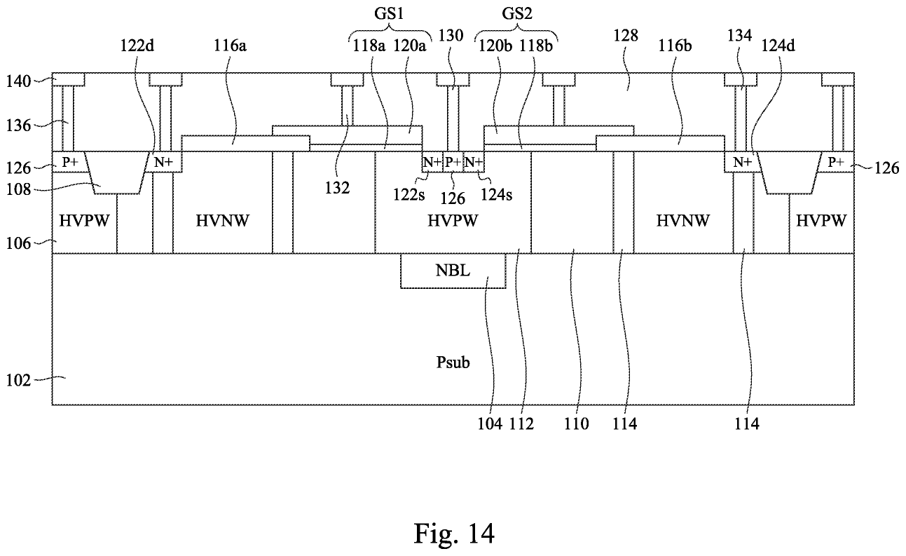

In FIG. 14, an interlayer dielectric (ILD) layer 128 is deposited to span across the LDMOS devices. The ILD layer 128 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (not shown) is deposited on the substrate gate structures GS1, GS2 and the p-type epitaxial layer 106 prior to depositing the ILD layer 128. The CESL may comprise a dielectric material, such as, silicon nitride, silicon oxide, silicon oxynitride, or the like, having a different etch rate than the material of the overlying ILD layer 128.

FIG. 14 further illustrates a shared contact 130 formed in the ILD layer 128 and over the p-type contact region 126. The shared contact 130 is electrically coupled to the p-type contact region 126, and the source regions 122s, 124s on opposite sides of the p-type contact region 126. For example, a shared silicide region may be formed to continuously across the source regions 122s, 124s and the p-type contact region 126, and the shared contact 130 is formed over the shared silicide region and electrically coupled to the source regions 122s, 124s and the p-type contact region 126. FIG. 14 further illustrates gate contacts 132 and drain contacts 134 formed in the ILD layer 128 and respectively over the gate electrodes 120a, 120b, and the drain regions 122d, 124d. FIG. 14 also illustrates substrate contacts 136 over the p-type contact regions 126 that are in contact with the isolation structures 108.

These contacts 130-136 may each comprise one or more metal layers, such as barrier layers, diffusion layers, and fill materials. For example, in some embodiments, the contacts 130-136 each include a barrier layer and a conductive material, and are electrically coupled to the underlying conductive features (e.g., silicide region). The barrier layer may include titanium, titanium nitride, tantalum, tantalum nitride, or the like. The conductive material may be copper, a copper alloy, silver, gold, tungsten, cobalt, aluminum, nickel, or the like. FIG. 14 further illustrates metal lines 140 extending above the contacts 130-136. The metal lines 140 may each comprise one or more metal layers, such as barrier layers, diffusion layers, and fill materials.

The contacts 130-136 and metal lines 140 can be formed by using, for example, a dual damascene process, such as forming trenches and contact openings in the ILD layer 128 in a trench-first or via-first approach using suitable photolithography and etching processes, depositing one or more layers of metal materials in the contact openings. Next, a planarization process, such as a CMP, may be performed to remove excess metal materials from a surface of the ILD layer 128.

FIG. 15 illustrates a method of forming an integrated circuit in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At block S101, one or more NBL layers are formed on a substrate. FIGS. 1-3 illustrate cross-sectional views of some embodiments corresponding to act in block S101.

At block S102, a p-type epitaxial layer is grown on the substrate. FIG. 4 illustrates a cross-sectional view of some embodiments corresponding to act in block S102.

At block S103, STI regions are formed in the p-type epitaxial layer. FIG. 5 illustrates a cross-sectional view of some embodiments corresponding to act in block S103.

At block S104, HVPWs and HVNWs are formed in the p-type epitaxial layer, with p-type slots interposing the HVNWs. FIGS. 6-10 illustrate cross-sectional views of some embodiments corresponding to act in block S104.

At block S105, Rox layers are formed on the HVNWs and p-type slots. FIG. 11 illustrates a cross-sectional view of some embodiments corresponding to act in block S105.

At block S106, gate structures are formed on the HVNWs and extend to a HVPW between the HVNWs. FIG. 12 illustrates a cross-sectional view of some embodiments corresponding to act in block S106.

At block S107, n-type source/drain regions and p-type contact regions are formed in the HVNWs and HVPWs. FIG. 13A illustrates a cross-sectional view of some embodiments corresponding to act in block S107.

At block S108, metal contacts and metal lines are formed over the n-type source/drain regions and p-type contact regions. FIG. 14 illustrates a cross-sectional view of some embodiments corresponding to act in block S108.

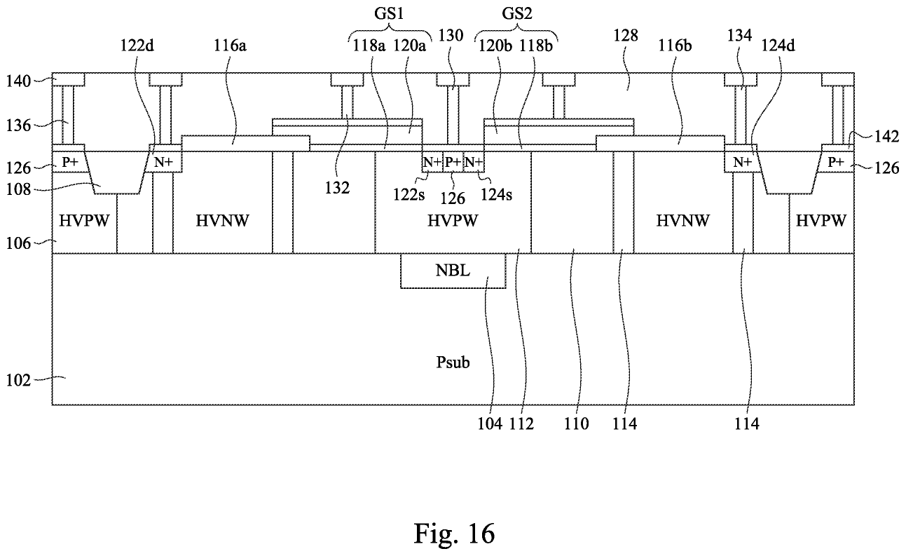

FIG. 16 illustrates a cross-sectional view of LDMOS devices in accordance with some embodiments of the present disclosure. The structure as illustrated in FIG. 16 is similar to that of FIG. 14, except that the structure in FIG. 16 includes silicide regions 142 formed over the gate electrodes 120a, 120b, the source regions 122s, 124s, the drain regions 122d, 124d, and the p-type contact regions 126, and the contacts 130-136 are formed over the respective silicide regions 142. In some embodiments, after the step of FIG. 13A is completed, the silicide regions 142 are formed by first depositing a metal (not shown) capable of reacting with the single-crystalline silicon of the underlying p-type epitaxial layer 106 and poly-crystalline silicon of the underlying gate electrodes 120a, 120b, such as nickel, cobalt, titanium, tantalum, platinum, tungsten, other noble metals, other refractory metals, rare earth metals or their alloys, over the exposed portions of the p-type epitaxial layer 106 and gate electrodes 120a, 120b, then performing a thermal anneal process to form silicide regions 142. The un-reacted portions of the deposited metal are then removed, e.g., by an etching process. Although the silicide regions 142 are referred to as silicide regions, silicide regions 142 may also be germanide regions, or silicon germanide regions (e.g., regions comprising silicide and germanide), if the p-type epitaxial layer 106 and/or gate electrodes 120a, 120b include germanium or silicon germanium.

As illustrated in FIG. 16, the source region 122s of the left LDMOS device, the source region 124s of the right LDMOS device, and a p-type contact region 126 share a common continuous silicide region 142. Therefore, the shared contact 130 can be electrically coupled to the source regions 122s, 124s and the p-type contact region 126 by using the common silicide region 142.

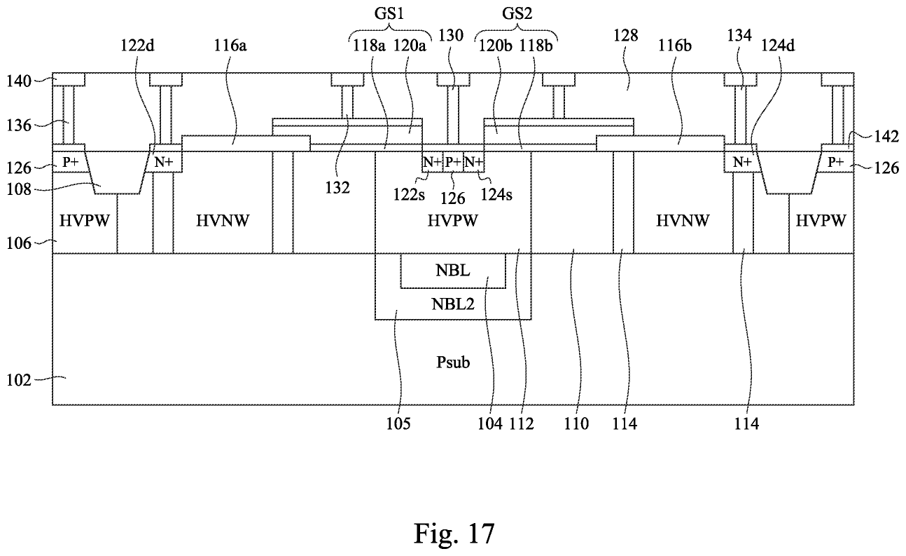

FIG. 17 illustrates a cross-sectional view of LDMOS devices in accordance with some embodiments of the present disclosure. The structure as illustrated in FIG. 17 is similar to that of FIG. 16, except that the structure in FIG. 17 further includes another n-type buried layer 105, labeled “NBL2” in FIG. 17, cupping an underside of the NBL 104. In some embodiments, the NBL2 105 is formed prior to epitaxially growing the p-type epitaxial layer 106 on the substrate. The NBL2 105 is formed by implanting an n-type impurity (e.g., phosphorus, arsenic, antimony, or the like) in the p-type substrate 102 at a dose of about 1E12 atoms/cm³ to about 1E14 atoms/cm³, and at an energy of about 50 KeV to about 300 KeV. In some embodiments, the NBL2 105 has an n-type impurity concentration less than the n-type impurity concentration of the NBL 104. The NBL2 105 can be formed before or after forming the NBL 104. In some embodiments, the NBL 2 104 extends past opposite sidewall boundaries of the NVPW to directly below HVNWs 110. By forming the high-dose NBL 104 and the low-dose NBL2 105 cupping the underside of the NBL 104 and keeping the high-dose NBL 104 and the low-dose NBL2 105 localized to the source sides of LDMOS devices, the breakdown voltage of LDMOS devices can be improved.

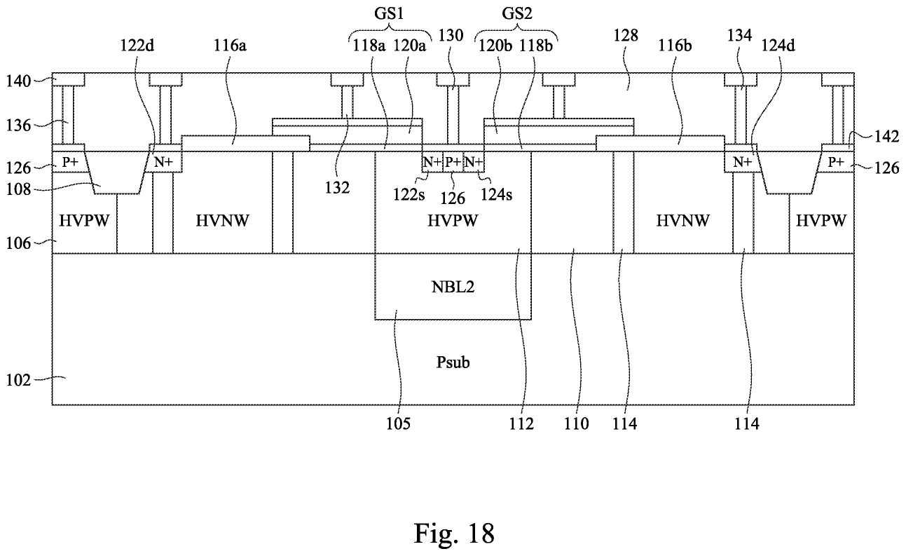

FIG. 18 illustrates a cross-sectional view of LDMOS devices in accordance with some embodiments of the present disclosure. The structure as illustrated in FIG. 18 is similar to that of FIG. 17, except that the high-dose NBL 104 is omitted in the structure of FIG. 18. In some embodiments, the low-dose NBL2 105 has opposite sidewall boundaries substantially aligned with sidewall boundaries of the HVPW 112. By forming the low-dose NBL2 105 localized to source sides of LDMOS devices, the breakdown voltage of LDMOS devices can be improved.

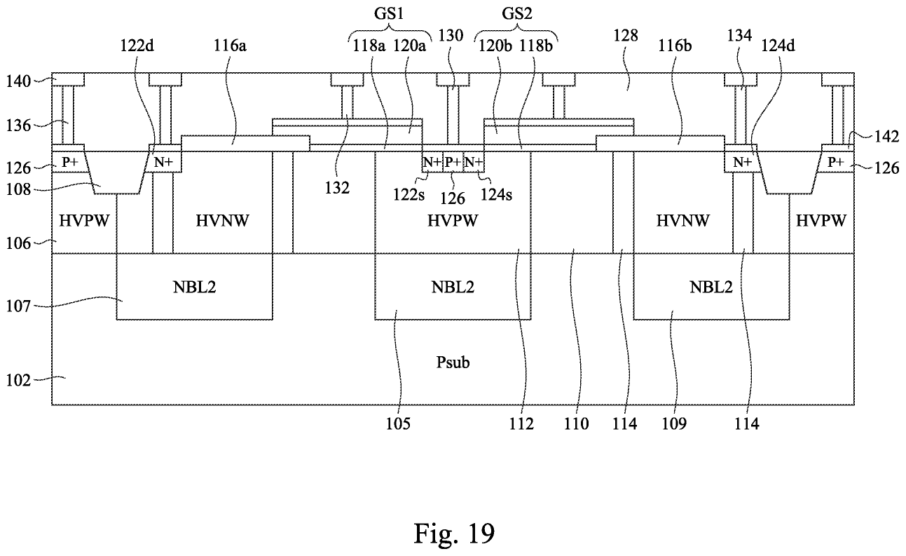

FIG. 19 illustrates a cross-sectional view of LDMOS devices in accordance with some embodiments of the present disclosure. The structure as illustrated in FIG. 19 is similar to that of FIG. 18, except that additional NBL2 regions 107 and 109 are formed directly below the drain regions 122d, and 124d respectively. In some embodiments, the NBL2 regions 107 and 109 are formed simultaneously with the NBL2 region 105, and thus have a same impurity type and concentration as the NBL2 region 105. The NBL2 regions 105, 107, 109 are spaced apart from each other, rather than a continuous n-type buried layer spanning across the HVNWs 110 and HVPWs 112. Such discontinuous NBL regions can result in an improved breakdown voltage of LDMOS devices.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that breakdown voltage of LDMOS devices can be increased to a range from 100 V to 200 V without performing dual epitaxy steps on the substrate. Another advantage is that the LDMOS devices with improved breakdown voltages can be widely used in various high power applications, such as a DC-DC Buck converter, an AC-DC Flyback controller, motor driver, and so on.

According to some embodiments, a device includes an epitaxial layer of a first conductivity type over a substrate, a plurality of wells of a second conductivity type in the epitaxial layer, and a first slot region of the first conductivity type in the epitaxial layer. The first slot region interposes a first one and a second one the plurality of wells of the second conductivity type. The device further includes a well of the first conductivity type forming an interface with a third one of the plurality of wells of a second conductivity type, a gate structure over the interface of the well of the first conductivity type and the third one of the plurality of wells of the second conductivity type, a first source/drain region in the well of the first conductivity type, and a second source/drain region in the first one and the second one of the plurality of wells of the second conductivity type. The second source/drain region is over the first slot region of the first conductivity type. In some embodiments, the first slot region of the first conductivity type has a bottom surface interfacing the substrate. In some embodiments, the first slot region of the first conductivity type has a top surface interfacing the second source/drain region. In some embodiments, the first slot region of the first conductivity type has a height less than a height of the well of the first conductivity. In some embodiments, the device further includes a second slot region of the first conductivity type in the epitaxial layer and interposing the second one and the third of the plurality of wells of the second conductivity type. In some embodiments, the second slot region of the first conductivity type has a top surface higher than a top surface of the first slot region. In some embodiments, the gate structure overlaps with the second slot region of the first conductivity type. In some embodiments, the device further includes a reduced surface field (RESURF) oxide layer extending from below the gate structure to the second source/drain region. The RESURF oxide layer is over the second slot region of the first conductivity type. In some embodiments, the RESURF oxide layer non-overlaps with the first slot region of the first conductivity type. In some embodiments, the gate structure comprises a gate dielectric layer and a gate electrode over the gate dielectric layer, and the RESURF oxide layer has a thickness greater than a thickness of the gate dielectric layer.

According to some embodiments, a device includes a p-type epitaxial layer over a substrate, a plurality of n-type wells in the p-type epitaxial layer, a p-type well interfacing a first one of the plurality of n-type wells, a first n-type buried layer in the substrate, a source region in the p-type well, a drain region in a second one of the plurality of n-type wells, and a gate structure laterally between the source region and the drain region. Each of the plurality of n-type wells has a bottom surface entirely in contact with the substrate. The p-type well overlaps with an entirety of the first n-type buried layer. In some embodiments, the first n-type buried layer has opposite sidewall boundaries laterally set back from opposite sidewall boundaries of the p-type well, respectively. In some embodiments, the first n-type buried layer overlaps with none of the plurality of n-type wells. In some embodiments, the device further includes a first p-type slot region directly below the gate structure, and the first p-type slot region spaces apart the first one of the n-type wells from the second one of the n-type wells. In some embodiments, the device further includes a second p-type slot region directly below the drain region, and the second p-type slot region spaces apart the second one of the n-type wells from a third one of the n-type wells. In some embodiments, the first p-type slot region has a top surface higher than a top surface of the second p-type slot region. In some embodiments, the device further includes a second n-type buried layer cupping an underside of the first n-type buried layer. The second n-type buried layer has an n-type impurity concentration lower than an n-type impurity concentration of the first n-type buried layer.

According to some embodiments, a method includes following stets. An n-type buried layer is formed in a substrate. A p-type epitaxial layer is epitaxially grown over the substrate and the n-type buried layer. A p-type well is formed over the n-type buried layer, and has a bottom surface extends past opposite sidewall boundaries of the n-type buried layer. A plurality of n-type wells are formed in the p-type epitaxial layer, and alternately arranged a plurality of slot regions within the p-type epitaxial layer. A gate structure is formed extending across an interface between the p-type well and a first one of the n-type wells. A source region is formed in the p-type well. A drain region is formed over a first one of the slot regions. In some embodiments, the gate structure is formed over a second one of the slot regions. In some embodiments, each of the plurality of n-type wells has a bottom surface entirely in contact with the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same puRPses and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
an epitaxial layer of a first conductivity type over a substrate;
a plurality of wells of a second conductivity type in the epitaxial layer;
a first slot region of the first conductivity type in the epitaxial layer, the first slot region interposing a first one and a second one the plurality of wells of the second conductivity type;
a well of the first conductivity type forming an interface with a third one of the plurality of wells of a second conductivity type;
a gate structure over the interface of the well of the first conductivity type and the third one of the plurality of wells of the second conductivity type;
a first source/drain region in the well of the first conductivity type; and
a second source/drain region in the first one and the second one of the plurality of wells of the second conductivity type, and over the first slot region of the first conductivity type.

2. The device of claim 1, wherein the first slot region of the first conductivity type has a bottom surface interfacing the substrate.

3. The device of claim 1, wherein the first slot region of the first conductivity type has a top surface interfacing the second source/drain region.

4. The device of claim 1, wherein the first slot region of the first conductivity type has a height less than a height of the well of the first conductivity type.

5. The device of claim 1, further comprising:
a second slot region of the first conductivity type in the epitaxial layer and interposing the second one and the third of the plurality of wells of the second conductivity type.

6. The device of claim 5, wherein the second slot region of the first conductivity type has a top surface higher than a top surface of the first slot region.

7. The device of claim 5, wherein the gate structure overlaps with the second slot region of the first conductivity type.

8. The device of claim 5, further comprising:
a reduced surface field (RESURF) oxide layer extending from below the gate structure to the second source/drain region, wherein the RESURF oxide layer is over the second slot region of the first conductivity type.

9. The device of claim 8, wherein the RESURF oxide layer non-overlaps with the first slot region of the first conductivity type.

10. The device of claim 8, wherein the gate structure comprises a gate dielectric layer and a gate electrode over the gate dielectric layer, and the RESURF oxide layer has a thickness greater than a thickness of the gate dielectric layer.

11. A device, comprising:
a p-type epitaxial layer over a substrate;
a plurality of n-type wells in the p-type epitaxial layer, each of the plurality of n-type wells having a bottom surface entirely in contact with the substrate;
a p-type well interfacing a first one of the plurality of n-type wells;
a first n-type buried layer in the substrate, the p-type well overlapping with an entirety of the first n-type buried layer;
a source region in the p-type well;
a drain region in a second one of the plurality of n-type wells; and
a gate structure laterally between the source region and the drain region.

12. The device of claim 11, wherein the first n-type buried layer has opposite sidewall boundaries laterally set back from opposite sidewall boundaries of the p-type well, respectively.

13. The device of claim 11, wherein the first n-type buried layer overlaps with none of the plurality of n-type wells.

14. The device of claim 11, further comprising:
a first p-type slot region directly below the gate structure, the first p-type slot region spacing apart the first one of the n-type wells from the second one of the n-type wells.

15. The device of claim 14, further comprising:
a second p-type slot region directly below the drain region, the second p-type slot region spacing apart the second one of the n-type wells from a third one of the n-type wells.

16. The device of claim 15, wherein the first p-type slot region has a top surface higher than a top surface of the second p-type slot region.

17. The device of claim 11, further comprising:
a second n-type buried layer cupping an underside of the first n-type buried layer, the second n-type buried layer has an n-type impurity concentration lower than an n-type impurity concentration of the first n-type buried layer.

18. A method, comprising:
forming an n-type buried layer in a substrate;
epitaxially growing a p-type epitaxial layer over the substrate and the n-type buried layer;
forming a p-type well over the n-type buried layer, the p-type well having a bottom surface extending past opposite sidewall boundaries of the n-type buried layer;
forming a plurality of n-type wells in the p-type epitaxial layer, wherein the plurality of n-type wells are alternately arranged a plurality of slot regions within the p-type epitaxial layer;
forming a gate structure extending across an interface between the p-type well and a first one of the n-type wells;
forming a source region in the p-type well; and
forming a drain region over a first one of the slot regions.

19. The method of claim 18, wherein the gate structure is formed over a second one of the slot regions.

20. The method of claim 18, wherein each of the plurality of n-type wells has a bottom surface entirely in contact with the substrate.
